(19) United States
(12) Patent Application Publication
(10) Pub. No.: US 2025/0248220 A1
(43) Pub. Date: Jul. 31, 2025

(54) VENTING HOLE ON PASSIVATION LAYER ON TOP OF GAP-FILL

(71) Applicant: Applied Materials, Inc., Santa Clara, CA (US)

(72) Inventor: Jungmin LEE, Santa Clara, CA (US)

(21) Appl. No.: 18/750,987

(22) Filed: Jun. 21, 2024

Related U.S. Application Data
(60) Provisional application No. 63/627,593, filed on Jan. 31, 2024.

(51) Int. Cl. H10K 59/122; H10K 59/12; H10K 59/80

(52) U.S. Cl. CPC H10K 59/122; H10K 59/1201; H10K 59/873

(57) ABSTRACT

Embodiments of the present disclosure relate to sub-pixel devices and methods related to relate to sub-pixel circuits and methods of forming sub-pixel circuits that may be utilized in a display such as an organic light-emitting diode (OLED) display. The sub-pixel includes a substrate, overhang pixel isolation structures (PIS), overhang structures, where the overhang structures include an extension disposed past a sidewall of the overhang structures, separation PIS, a metal structure disposed over the substrate, an inorganic layer disposed over each overhang PIS and over each separation PIS, where the inorganic layer includes a plurality of openings, organic light-emitting diode (OLED) material disposed over the metal structure, where the OLED material is disposed between the inorganic layer under each extension of the overhang structures, and a cathode disposed over the OLED material.

### CROSS-REFERENCE TO RELATED APPLICATION

This application claims the benefit of U.S. Provisional Patent Application No. 63/627,593, filed Jan. 31, 2024, which is incorporated by reference herein in its entirety.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are improved sub-pixel circuits and methods of forming sub-pixel circuits.

### SUMMARY

Embodiments described herein generally relate to a display. More specifically, embodiments described herein relate to sub-pixel circuits and methods of forming sub-pixel circuits that may be utilized in a display such as an organic light-emitting diode (OLED) display.

In one embodiment, a sub-pixel is provided. The sub-pixel includes a substrate, overhang pixel isolation structures (PIS), overhang structures, where the overhang structures include an extension disposed past a sidewall of the overhang structures, separation PIS, a metal structure disposed over the substrate, an inorganic layer disposed over each overhang PIS and over each separation PIS, where the inorganic layer includes a plurality of openings, organic light-emitting diode (OLED) material disposed over the metal structure, where the OLED material is disposed between the inorganic layer under each extension of the overhang structures, and a cathode disposed over the OLED material.

In another embodiment, a sub-pixel is provided. The sub-pixel includes overhang structures disposed over a substrate including an extension disposed past a sidewall of the overhang structures, a metal structure disposed over the substrate, an inorganic layer disposed under each extension of the overhang structures, the inorganic layer including a plurality of openings. The sub-pixel is made by a process including depositing an organic light-emitting diode (OLED) material over the substrate, the OLED is disposed over the metal structure, wherein the inorganic layer under each extension of the overhang structures is disposed between the OLED material, and depositing a cathode, wherein the cathode is disposed under each extension of the overhang structures.

In yet another embodiment, a method is provided. The method includes depositing an inorganic layer over a substrate. The substrate includes a plurality of metal structures, a plurality of overhang pixel isolation structures (PIS) and a plurality of separation PIS. The method further includes removing portions of the inorganic layer, such that the inorganic layer includes a plurality of openings, such that the inorganic layer is at least partially disposed over the plurality of overhang PIS, and such that the inorganic layer is at least partially disposed over a plurality of separation PIS, forming overhang structures over the inorganic layer disposed over a plurality of overhang PIS, the overhang structures include an extension disposed past a sidewall of the overhang structures, depositing an organic light-emitting diode (OLED) material over the substrate, the OLED material is disposed over the metal structures and the inorganic layer under each extension of the overhang structures; and depositing a cathode, where the cathode is disposed under each extension of the overhang structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit along a pixel-line at section line 1A-1A, according to one or more embodiments.

FIG. 1B is a schematic, cross-sectional view of an overhang structure of the sub-pixel circuit of FIG. 1A, according to one or more embodiments.

FIG. 1C is a schematic, cross-sectional view of a sub-pixel circuit along a pixel-line 1A-1A showing an arrangement of a plurality of openings, according to one or more embodiments.

FIG. 1D is a schematic, cross-sectional view of a sub-pixel circuit along the line plane at section line 1B-1B, according to one or more embodiments.

FIG. 2 is a schematic, top view of a sub-pixel circuit having a line-type architecture according to embodiments.

FIG. 3 is a flow diagram of a method for forming a sub-pixel circuit, according to one or more embodiments.

FIGS. 4A-4K are schematic, cross-sectional views of a substrate during a method of FIG. 3 for forming a sub-pixel circuit, according to one or more embodiments

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. The sub-pixel circuits can include pixel structures, each pixel structure includes at least one outgassing hole thereby allowing moisture that is absorbed during the fabrication process to be released. The release of the absorbed moisture prevents cracking of the passivation layer.

In one embodiment, a sub-pixel is provided. The sub-pixel includes a substrate, a metal structure (e.g., an anode), overhang structures, overhang pixel isolation structures (PIS), separation PIS, an organic light emitting diode (OLED) material, an inorganic layer including a plurality of openings (e.g., vent holes), and a cathode. The anode is defined by adjacent first overhang structure and adjacent second overhang structure. The overhang structures are disposed over the overhang PIS. The overhang structures include a second structure disposed over the first structure. A bottom surface of the second structure extends laterally past an upper surface of the first structure. The OLED material is disposed over the anode and an upper surface of the inorganic layer. The cathode disposed over the OLED material and an upper surface of the inorganic layer under the extensions of the second structures of the adjacent overhang structures. In one or more embodiments, the inorganic layer is deposited over the overhang PIS and the separation PIS. The overhang PIS and the separation PIS may be known as gap-fill between adjacent anodes.

Each of the embodiments described herein of the sub-pixel circuit include a plurality of sub-pixels. Each of the sub-pixels is defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more subpixels. Each sub-pixel includes OLED materials configured to emit a white, red, green, blue or other color light when energized. For example, the OLED materials of a first sub-pixel emits a red light when energized, the OLED materials of a second sub-pixel emits a green light when energized, and the OLED materials of a third sub-pixel emits a blue light when energized.

The overhangs are permanent to the sub-pixel circuit and include at least a second structure disposed over a first structure. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)) and a cathode. In some instances, an encapsulation layer may be disposed via evaporation deposition. In embodiments including one or more capping layers, the capping layers are disposed between the cathode and the encapsulation layer. The overhang structures and the evaporation angle set by the evaporation source define the deposition angles. For example, the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer of a respective subpixel is disposed over the cathode with the encapsulation layer extending under at least a portion of each of the adjacent overhang structures and along a sidewall of each of the adjacent overhang structures.

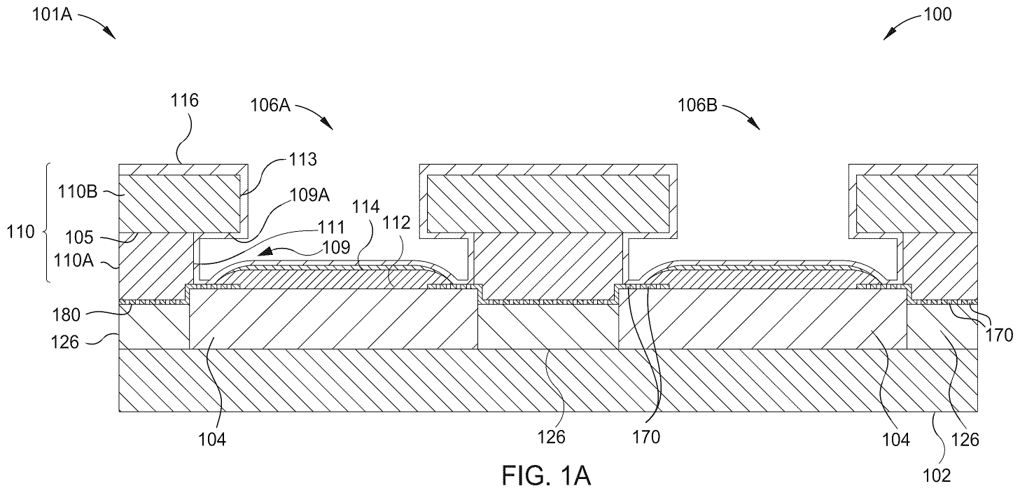

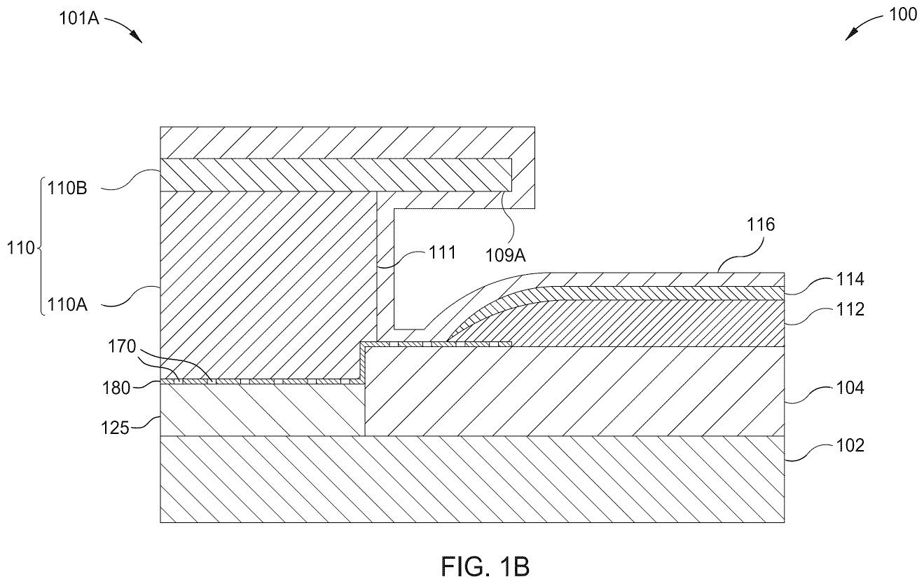

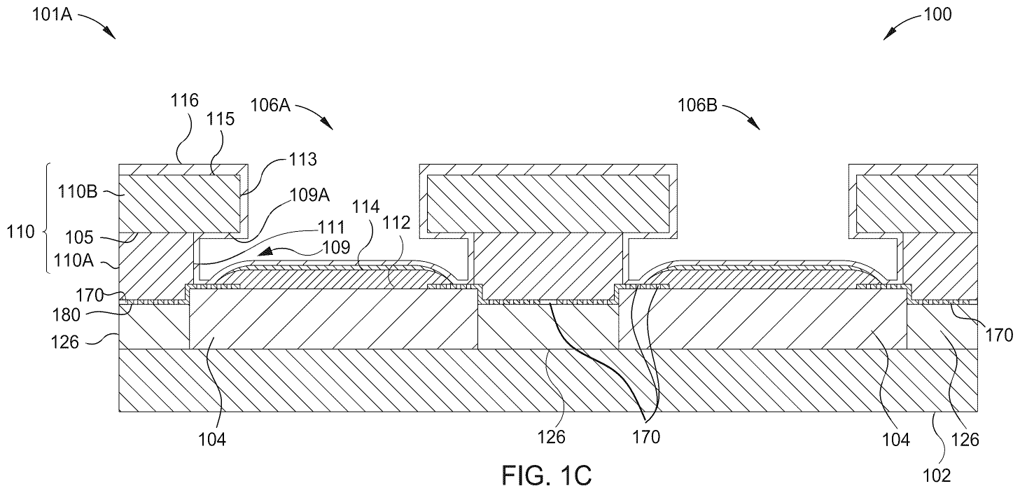

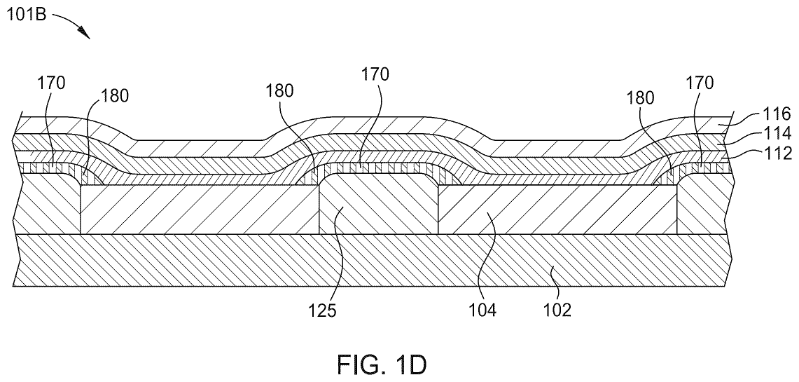

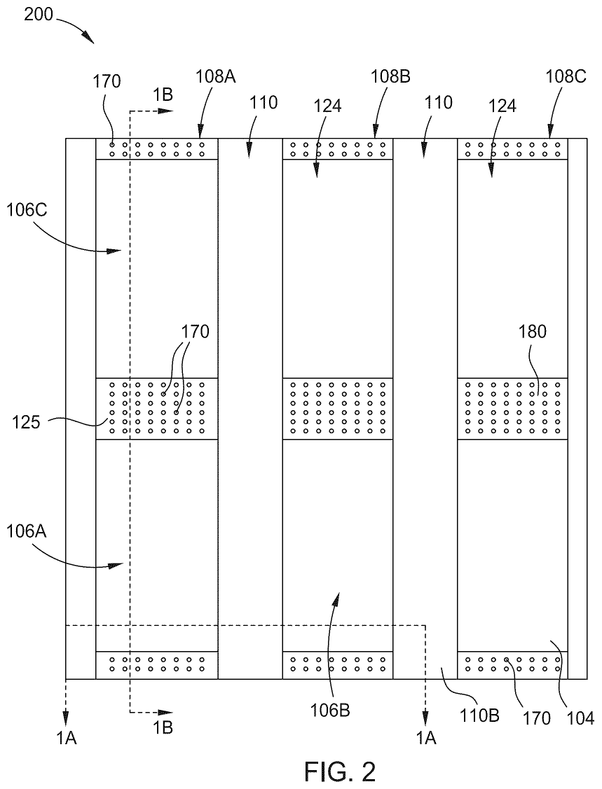

FIG. 1A is a schematic, cross-sectional view of a sub-pixel circuit 100, according to one or more embodiments. The cross-sectional view of FIG. 1A is taken along section line 1A-1A of FIG. 2 (e.g., a pixel plane 101A). The pixel plane 101A corresponds to an X-direction. FIG. 1B is a schematic, cross-sectional view of an overhang structure 110 of the sub-pixel circuit 100 of FIG. 1A, according to one or more embodiments. FIG. 1C is a schematic, cross-sectional view of a sub-pixel circuit 100, according to one or more embodiments. The cross-sectional view of FIG. 1C is taken along section line 1B-1B of FIG. 2 (e.g., a line plane 101B). The line plane 101B corresponds to a Y-direction.

The sub-pixel circuit 100 includes a substrate 102. In one or more embodiments, a plurality of metal structures 104 are pre-patterned on the substrate 102. For example, the substrate is pre-patterned with metal structures 104 (e.g., anodes) including a metal-containing material. The metal-containing material includes indium tin oxide (ITO), chromium, chromic oxide (Cr₂O₃), titanium, gold, silver, copper, aluminum, a transparent conductive oxide (TCO), combinations thereof, or other suitably conductive materials. The metal structures 104 are configured to operate as anodes of respective sub-pixels. In some embodiments, the metal structures 104 are a layer stack of a first transparent conductive oxide (TCO) layer, a second metal-containing layer disposed on the first TCO layer, and a third TCO layer disposed on the second metal-containing layer.

One or more overhang pixel isolation structures (PIS) 126 are disposed over the substrate 102. The overhang PIS 126 includes one of an organic material, an organic material with an inorganic coating disposed thereover, or an inorganic material. The organic material of the overhang PIS 126 includes, but is not limited to, polyimides. The inorganic material of the overhang PIS 126 includes, but is not limited to, silicon oxide (SiO₂), silicon nitride (Si₃N₄), silicon oxynitride (Si₂N₂O), magnesium fluoride (MgF₂), or combinations thereof.

As shown in FIG. 1A, FIG. 1B, and FIG. 1C, the sub-pixel circuit 100 includes an inorganic layer 180 at least partially disposed over the overhang PIS 126. The overhang PIS 126 may also be known as gap-fill between adjacent anodes. In some embodiments, the inorganic layer 180 is a passivation layer. The inorganic layer may include aluminum oxide (Al₂O₃). The inorganic layer 180 includes a plurality of openings 170 (e.g., vent holes). The plurality of openings 170 are disposed through the top surface of the inorganic layer 180 to the uppermost surface of the overhang PIS 126. The openings 170 of the inorganic layer 180 are disposed in an array. In some embodiments, the openings 170 extend through the overhang PIS 126. Each opening in the plurality of openings 170 is evenly spaced along the inorganic layer 180 disposed over the overhang PIS 126. In some embodiments, as shown in FIG. 1C, one opening of the plurality of openings 170 includes a larger diameter compared to the surrounding plurality of openings 170, the plurality of openings 170 include the same diameter. In other embodiments, the inorganic layer 180 includes a single opening. In the embodiment where there is a single opening in the inorganic layer 180, the single opening accounts for about 20 percent of the surface area of the inorganic layer 180. The openings 170 allow for out-gassing of moisture that is absorbed by the substrate 102, the overhang PIS 126, and/or the metal structures 104. Outgassing moisture that is absorbed by the substrate 102, the overhang PIS 126, and/or the metal structures 104 may reducing cracking of an inorganic layer 180 and/or pixel degradation during fabrication processes.

As shown in FIG. 1D, the sub-pixel circuit 100 includes separation PIS 125. Each sub-pixel line (e.g., a first sub-pixel line 108A, a second sub-pixel line 108B, or a third sub-pixel line 108C as shown in FIG. 2) includes separation PIS 125, with adjacent sub-pixels sharing the separation PIS 125. The separation PIS 125 are permanent to the sub-pixel circuit 100. The separation PIS 125 further define each sub-pixel (e.g., a first sub-pixel 106A and a third sub-pixel 106C) of a first sub-pixel line 108A of the sub-pixel circuit 100. The separation PIS 125 may also be known as gap-fill between adjacent anodes. In some embodiments, an inorganic layer 180 is disposed over the separation PIS 125. In some embodiments, the inorganic layer 180 may be a passivation layer. The inorganic layer may include aluminum oxide (Al₂O₃). The inorganic layer 180 is disposed at least partially over the separation PIS 125. The plurality of openings 170 are disposed through the top surface of the inorganic layer 180 to the uppermost surface of the separation PIS 125. The inorganic layer 180 includes a plurality of openings 170 (e.g., vent holes). The openings 170 of the inorganic layer 180 are disposed in an array. The plurality of openings 170 account for about 20 percent of the surface area of the inorganic layer 180 that is disposed over the separation PIS 125. Each opening in the plurality of openings 170 is evenly spaced along the inorganic layer 180. In some embodiments, one opening of the plurality of openings 170 includes a larger diameter compared to the surrounding plurality of openings 170, the plurality of openings 170 include the same diameter. In other embodiments, the inorganic layer 180 includes a single opening. In the embodiment where there is a single opening in the inorganic layer 180, the single opening accounts for about 20 percent of the surface area of the inorganic layer 180. The openings 170 allow for out-gassing of moisture that is absorbed by the substrate 102, the separation PIS 125, and/or the metal structures 104. Outgassing moisture that is absorbed by the substrate 102, the overhang PIS 126, and/or the metal structures 104 may reducing cracking of an inorganic layer 180 and/or pixel degradation during fabrication processes.

The sub-pixel circuit 100 has a plurality of sub-pixel lines (e.g., a first sub-pixel line 108A, a second sub-pixel line 108B, or a third sub-pixel line 108C as shown in FIG. 2). The sub-pixel lines (e.g., a first sub-pixel line 108A, a second sub-pixel line 108B and a third sub-pixel line 108C) are adjacent to each other along the pixel plane. While FIG. 1A depicts the first sub-pixel line 108A and the second sub-pixel line 108B, the sub-pixel circuit 100 of the embodiments described herein may include two or more sub-pixel lines, such as a third sub-pixel line and a fourth sub-pixel. Each sub-pixel line has OLED materials configured to emit a white, red, green, blue or other color light when energized. In some embodiments, the OLED materials within a pixel line (e.g., a first sub-pixel line 108A, a second sub-pixel line 108B and a third sub-pixel line 108C) are configured to emit the same color light when energized. In other embodiments, the OLED materials within a pixel line (e.g., a first sub-pixel line 108A, a second sub-pixel line 108B and a third sub-pixel line 108C) are configured to emit different colors of light when energized. For example, the OLED materials of the first sub-pixel line 108A emits a red light when energized, the OLED materials of the second sub-pixel line 108B emits a green light when energized, the OLED materials of the third sub-pixel line 108C emits a blue light when energized, and the OLED materials of a fourth sub-pixel (not pictured) emits another color light when energized. For example, the OLED materials of the first sub-pixel 106A emit a red light when energized and the OLED materials of the second sub-pixel 106B emit a green light when energized.

Each sub-pixel line includes overhang structures 110, with adjacent sub-pixel lines sharing the overhang structures 110 in the pixel plane. The overhang structures 110 are permanent to the sub-pixel circuit 100. The overhang structures 110 further define each sub-pixel line of the sub-pixel circuit 100. Each overhang structure 110 includes adjacent overhangs 109. The adjacent overhangs 109 are defined by an overhang extension 109A of a second structure 110B extending laterally past an upper surface 105 of a first structure 110A.

In some embodiments, the first structure 110A is a non-conductive inorganic material. The non-conductive materials of the first structure 110A include titanium and/or an inorganic silicon-containing material, for example, amorphous silicon (a-Si), silicon nitride (Si₃N₄), silicon oxide (SiO₂), silicon oxynitride (Si₂N₂O), or combinations thereof. In some embodiments, the first structure 110A includes conductive materials. The conductive materials of the first structure 110A include aluminum (Al), aluminum neodymium (AlNd), molybdenum (Mo), molybdenum tungsten (MoW), copper (Cu), or combinations thereof. In some embodiments, the second structure 110B is a conductive inorganic material. The conductive inorganic materials of the second structure 110B include a metal-containing material, for example, copper (Cu), chromium (Cr), aluminum (AI), aluminum neodymium (AlNd), molybdenum (Mo), molybdenum tungsten (MoW), or combinations thereof. In some embodiments, the second structure 110B includes inorganic materials. The inorganic materials include titanium (Ti), silicon nitride (SisN4), silicon oxide (SiO₂), silicon oxynitride (Si₂N₂O), or combinations thereof.

The overhang extension 109A of the second structure 110B forms the adjacent overhangs 109 and allows for the second structure 110B to shadow the first structure 110A. The shadowing of the adjacent overhangs 109 provides for evaporation deposition of an OLED material 112 and a cathode 114. The OLED material 112 may include one or more of a hole injection layer (HIL), a hole transport layer (HTL), an emissive layer (EML), and an electron injection layer (EIL), and an electron transport layer (ETL). The OLED material 112 is disposed over and in contact with the metal structures 104. The OLED material 112 is disposed under adjacent overhangs 109 and may contact a sidewall 113 of the first structure 110A. In one embodiment, the OLED material 112 is different from the material of the first structure 110A, the second structure 110B, and the overhang PIS 126. The cathode 114 is disposed over the OLED material 112 and extends under the adjacent overhangs 109. The cathode 114 extends past an endpoint of the OLED material 112.

The cathode 114 includes a conductive material, such as a metal. For example, the cathode 114 includes, but is not limited to, silver, magnesium, chromium, titanium, aluminum, ITO, or a combination thereof. In one embodiment, material of the cathode 114 is different from the material of the first structure 110A and the second structure 110B. In one or more embodiments the OLED material 112 and the cathode 114 do not contact the sidewall 111 of the first structure 110A. In one or more embodiments, the OLED material 112 contacts the sidewall 111 of the first structure 110A.

Each sub-pixel (e.g., a first sub-pixel 106A and a second sub-pixel 106B) includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the overhang extension 109A and along a sidewall 111 of each of the first structure 110A and the second structure 110B. The encapsulation layer 116 is disposed over the cathode 114 and extends past the cathode 114, between the cathode and the sidewall 111, and at least partially over the sidewall 111. In some embodiments, the encapsulation layer 116 extends to contact the sidewall 111 of the first structure 110A. In the illustrated embodiment in FIG. 1A, the encapsulation layer 116 extends to contact the second structure 110B at an underside surface of the overhang extension 109A, the sidewall 113 of the second structure 110B, and the upper surface 115 of the second structure 110B. In some embodiments, the encapsulation layer 116 extends to contact the second structure 110B at an underside surface of the overhang extension 109A and to be disposed over the inorganic layer 180, the OLED material 112, and the cathode 114. In other embodiments, the encapsulation layer 116 ends at the sidewall 111 of the first structure 110A (e.g., is not disposed over the sidewall 113 of the second structure 110B, the upper surface 115 of the second structure 110B, or the underside surface of the overhang extension 109A of the overhang structures 110). The encapsulation layer 116 includes the non-conductive inorganic material, such as the silicon-containing material. The silicon-containing material may include Si₃N₄ containing materials.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the sub-pixel circuit 100 further includes at least a global passivation layer disposed over the overhang structure 110 and the encapsulation layer 116. In yet another embodiment, the sub-pixel includes an intermediate passivation layer disposed over the overhang structures 110 of each of the sub-pixels (e.g., a first sub-pixel 106A and a second sub-pixel 106B), and disposed between the encapsulation layer 116 and the global passivation layer.

FIG. 2 is a schematic, top view of sub-pixel circuit 100, having a line-type architecture 200 according to embodiments. The line-type architecture 200 includes a plurality of pixel openings 124. Each of pixel opening 124 is abutted by overhang structures 110 and a separation PIS 125 which define each of the sub-pixel line (e.g., a first sub-pixel line 108A, a second sub-pixel line 108B and a third sub-pixel line 108C) and sub-pixel pixel (e.g., a first sub-pixel 106A and a second sub-pixel 106B) of the line-type architecture 200. Evaporation deposition is utilized for deposition of OLED materials (including a hole injection layer (HIL), a hole transport layer (HTL), an emissive layer (EML), and an electron transport layer (ETL)). Evaporation deposition is used for deposition of inorganic materials and cathode material. In some instances, an encapsulation layer may be disposed via evaporation deposition. In embodiments including one or more capping layers, the capping layers are disposed between the cathode and the encapsulation layer. The overhang structures and the evaporation angle set by the evaporation source define the deposition angles, i.g., the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer of a respective subpixel is disposed over the cathode with the encapsulation layer extending under at least a portion of each of the adjacent overhang structures and along a sidewall of each of the adjacent overhang structures.

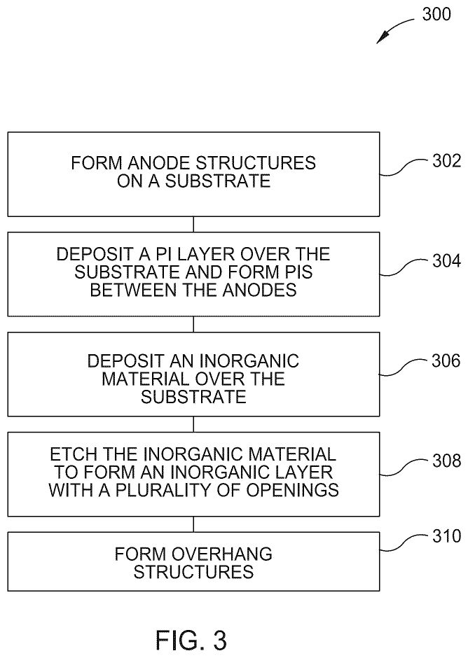

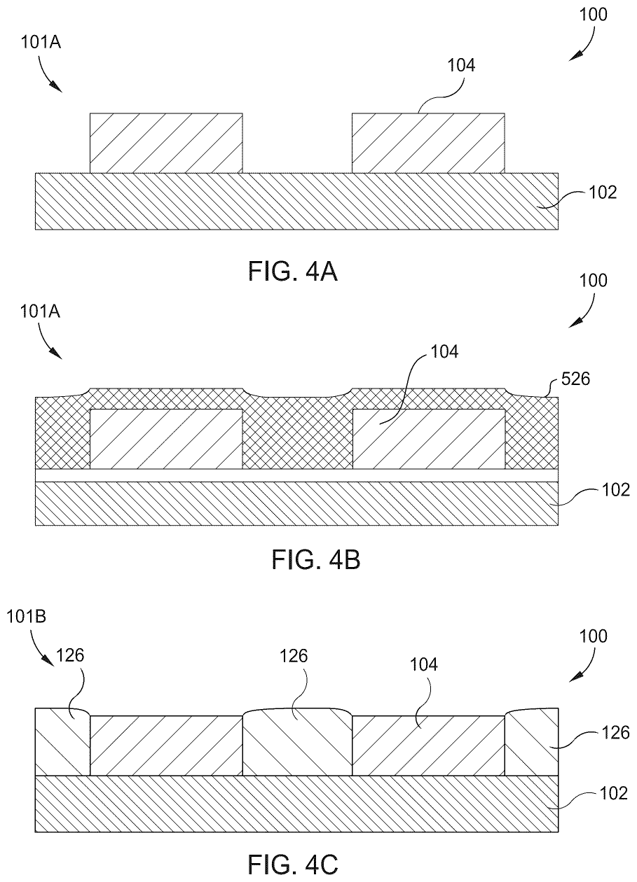

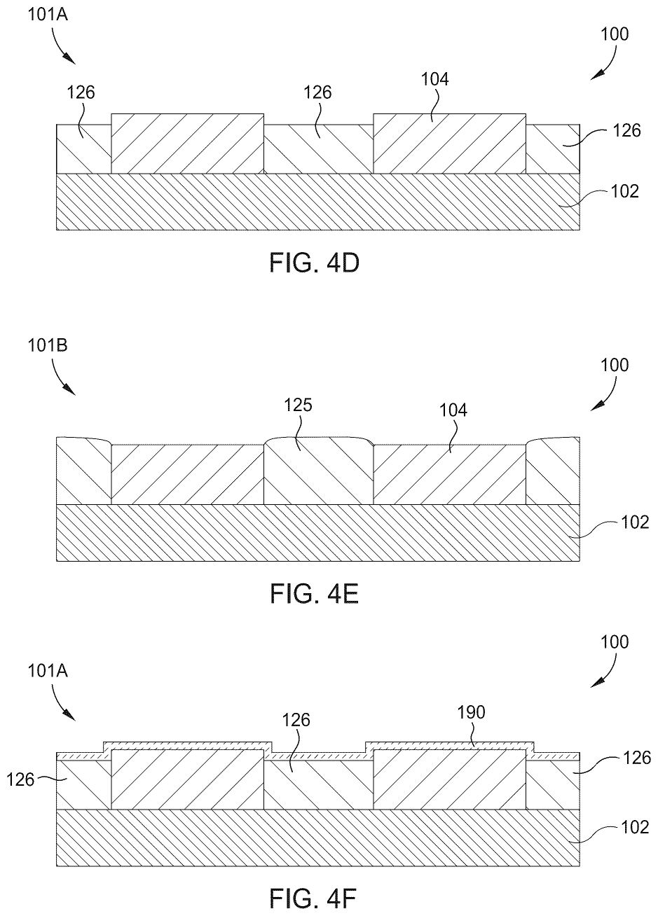

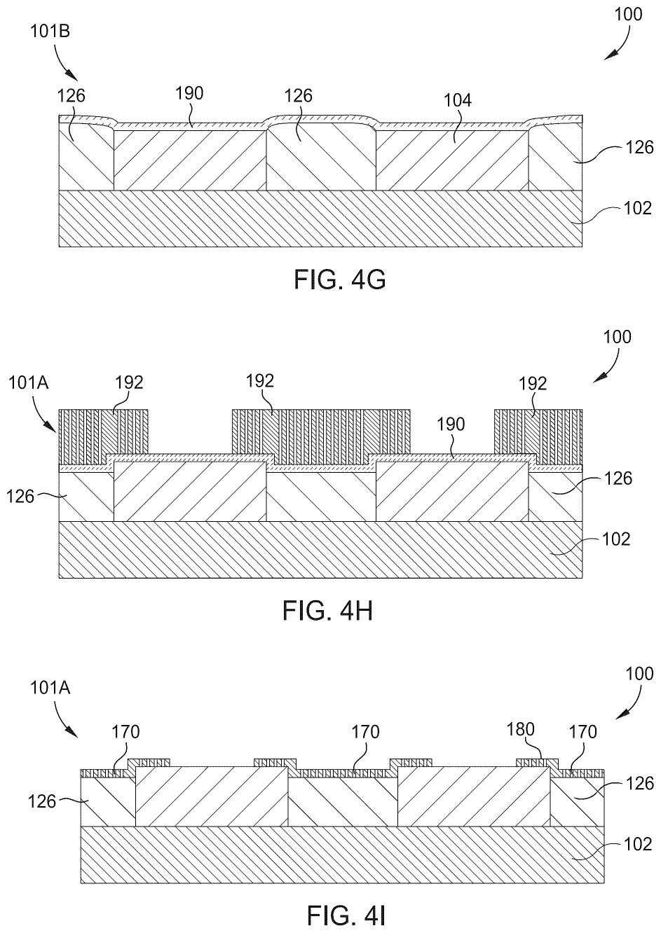

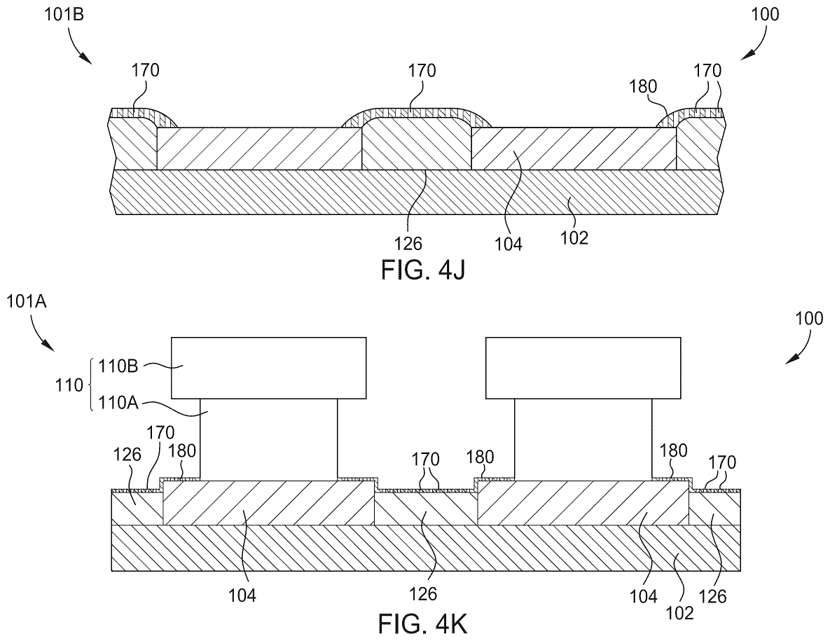

FIG. 3 is a flow diagram of method 300 for forming a sub-pixel circuit 100 with an inorganic layer 180 including a plurality of openings 170 disposed over an overhang PIS 126 and separation PIS 125, according to one or more embodiments. FIG. 4A-4K are schematic, cross-sectional views of substrate 102 during the method 300 for forming the sub-pixel circuit 100.

At operation 302, as shown in FIG. 4A, metal structures 104 (e.g., anodes) are formed over a substrate. This can be done by depositing a metal structures 104 over the substrate 102, and then depositing a photoresist pattern over the metal structures 104. The metal structures 104 (not protected by a photoresist pattern) is then etched away forming the desired pattern of the metal structures 104 (e.g., anode structures).

At operation 304, as shown in FIGS. 4B-4D (along the pixel plane 101A, section line 1A-1A shown in FIG. 2), a pixel isolation (PI) layer 526 is deposited over the metal structures 104 and the substrate 102. The PI layer 526 as show in FIG. 4B is deposited over the metal structures 104 and the substrate 102. The PI layer 526 is then etched away to form overhang PIS 126 in between the metal structures 104 as shown in FIG. 4C. The overhang PIS 126 are then planarized such that that a top surface of each overhang PIS 126 are aligned with one another and are below an upper surface of the metal structures 104 as shown in FIG. 4D.

At operation 304, as shown in as shown in FIG. 4E (along the line plane 101B, section line 1B-1B shown in FIG. 2), the PI layer 526 is deposited over the metal structures 104 and the substrate 102. The PI layer 526 is then etched away to form separation PIS 125 between the metal structures 104 as shown in FIG. 4E.

At operation 306, as shown in FIG. 4F (along the pixel plane 101A, section line 1A-1A shown in FIG. 2), an inorganic material 190 is deposited over the metal structures 104 and the overhang PIS 126. In one or more embodiments, the inorganic material 190 is deposited using evaporation deposition. As shown in FIG. 4G (along the line plane, 1B-1B shown in FIG. 2), the inorganic material 190 is deposited over the anodes 104 and isolation PIS 125.

At operation 308, a photoresist 192 is disposed over portions of the inorganic material 190. The photoresist 192, as shown in FIG. 4H (along the pixel plane 101A, section line 1A-1A shown in FIG. 2), is patterned to protect portions of the inorganic material 190 from the etching process. The photoresist 192 is also patterned of the separation PIS 125. The inorganic material 190 that is not protected by the photoresist 192 is then etched away to form an inorganic layer 180 with a plurality of openings 170 (e.g., vent holes) over the overhang PIS 126 and the separation PIS 125. The photoresist 192 is then removed. As shown in FIG. 4I (along the pixel plane, 1A-1A shown in FIG. 2) the inorganic layer 180 is patterned to at least partially cover the overhang PIS 126 and includes a plurality of openings 170. As shown in FIG. 4J (along the line plane 101B, section line 1B-1B shown in FIG. 2), the inorganic layer 180 at least partially covers the separation PIS 125 and includes a plurality of openings 170.

At operation 310 as shown in FIG. 4I (along the pixel plane 101A, section line 1A-1A shown in FIG. 2), overhang structures 110 are formed over each overhang PIS 126. The overhang structures 110, as shown in FIG. 4J, can be formed by depositing a first overhang layer and a second overhang layer, and etching away the desired areas using a photoresist in order to form the overhang structures

After operation 310, further processing may occur. For example, deposition of OLED materials, a cathode, and an encapsulation layer may occur to complete the sub-pixel circuit 100. Operations may repeat until the number of desired sub-pixels are formed.

Overall, the sub-pixel circuits of the present disclosure can include an inorganic layer (e.g., a passivation layer) including a plurality of openings (e.g., vent holes) disposed over overhang PIS and separation PIS in a pixel line. The vent holes allow for moisture that is absorbed by the substrate, the anodes, the overhang PIS and/or the separation PIS during processing to be released. The release of moisture through the vent holes prevents cracking of the passivation layer and/or damage to the pixel line.

While the foregoing is directed to embodiments of the present disclosure, other and further embodiments of the disclosure may be devised without departing from the basic scope thereof, and the scope thereof is determined by the claims that follow.

1. A sub-pixel, comprising:
a substrate;
overhang pixel isolation structures (PIS);
overhang structures, the overhang structures including an extension disposed past a sidewall of the overhang structures;
separation PIS;
a metal structure disposed over the substrate;
an inorganic layer disposed over each overhang PIS and over each separation PIS, the inorganic layer including a plurality of openings;
organic light-emitting diode (OLED) material disposed over the metal structure, wherein the OLED material is disposed between the inorganic layer under each extension of the overhang structures; and
a cathode disposed over the OLED material.

2. The sub-pixel of claim 1, wherein adjacent overhang PIS have the metal structure disposed therebetween.

3. The sub-pixel of claim 1, wherein adjacent separation PIS have the metal structure disposed therebetween.

4. The sub-pixel of claim 1, wherein the inorganic layer comprises aluminum oxide (Al₂O₃).

5. The sub-pixel of claim 1, wherein the overhang structures include a second structure disposed over a first structure.

6. The sub-pixel of claim 1, further comprising an encapsulation layer disposed over the cathode and past an endpoint of the cathode.

7. The sub-pixel of claim 1, wherein the plurality of openings comprise about 20 percent of the inorganic layer.

8. The sub-pixel of claim 1, wherein the plurality of openings extend through the inorganic layer to a top surface of the separation PIS or an upper surface of the overhang PIS.

9. A sub-pixel, the sub-pixel comprising overhang structures disposed over a substrate including an extension disposed past a sidewall of the overhang structures, a metal structure disposed over the substrate, an inorganic layer disposed under each extension of the overhang structures, the inorganic layer including a plurality of openings, the sub-pixel is made by a process comprising:
depositing an organic light-emitting diode (OLED) material over the substrate, the OLED is disposed over the metal structure, wherein the inorganic layer under each extension of the overhang structures is disposed between the OLED material; and
depositing a cathode, wherein the cathode is disposed under each extension of the overhang structures.

10. The sub-pixel of claim 9, wherein the inorganic layer is deposited using evaporation deposition.

11. The sub-pixel of claim 9, further including overhang pixel isolation structures (PIS) disposed under the overhang structures.

12. The sub-pixel of claim 11, wherein adjacent overhang PIS have the metal structure disposed therebetween.

13. The sub-pixel of claim 9, further including separation pixel isolation structures (PIS), adjacent separation PIS have the metal structure disposed therebetween.

14. The sub-pixel of claim 9, further comprising:
an encapsulation layer disposed over the cathode and past an endpoint of the cathode, wherein the encapsulation layer extends under at least a portion of the extensions of overhang structures, along the sidewall of the overhang structures, and contacts a bottom surface of the extensions of the overhang structures.

15. A method, comprising:
depositing an inorganic layer over a substrate, the substrate including a plurality of metal structures, a plurality of overhang pixel isolation structures (PIS) and a plurality of separation PIS;
removing portions of the inorganic layer, such that the inorganic layer includes a plurality of openings, such that the inorganic layer is at least partially disposed over the plurality of overhang PIS, and such that the inorganic layer is at least partially disposed over a plurality of separation PIS;
forming overhang structures over the inorganic layer disposed over a plurality of overhang PIS, the overhang structures including an extension disposed past a sidewall of the overhang structures;
depositing an organic light-emitting diode (OLED) material over the substrate, the OLED material is disposed over the metal structures and the inorganic layer under each extension of the overhang structures; and
depositing a cathode, wherein the cathode is disposed under each extension of the overhang structures.

16. The method of claim 15, further comprising:
depositing an encapsulation layer over the cathode and past an endpoint of the cathode, wherein the encapsulation layer extends under at least a portion of the extensions of overhang structures, along the sidewall of the overhang structures, and contacts a bottom surface of the extensions of the overhang structures.

17. The method of claim 15, wherein the plurality of openings extend through the inorganic layer to a top surface of the separation PIS or an upper surface of the overhang PIS.

18. The method of claim 15, wherein portions of the inorganic layer are removed by an etching process.

19. The method of claim 15, wherein the inorganic layer comprises aluminum oxide (Al₂O₃).

20. The method of claim 15, the plurality of openings extend through the inorganic layer to a top surface of the separation PIS or an upper surface of the overhang PIS.
